(19) United States
(12) Patent Application Publication
(10) Pub. No.: US 2025/0174529 A1
(43) Pub. Date: May 29, 2025

(54) SEMICONDUCTOR DEVICE AND SEMICONDUCTOR PACKAGE INCLUDING THE SAME

(71) Applicant: SAMSUNG ELECTRONICS CO., LTD., Suwon-si (KR)

(72) Inventors: Byungho KIM, Suwon-si (KR); Yeohoon YOON, Suwon-si (KR)

(73) Assignee: SAMSUNG ELECTRONICS CO., LTD., Suwon-si (KR)

(21) Appl. No.: 18/939,868

(22) Filed: Nov. 7, 2024

(30) Foreign Application Priority Data
Nov. 29, 2023 (KR) 10-2023-0169855

(51) Int. Cl. H01L 23/495; H01L 23/31; H01L 23/498

(52) U.S. Cl. CPC H01L 23/49568; H01L 23/3107; H01L 23/49541; H01L 23/49582; H01L 23/49861

(57) ABSTRACT

A semiconductor device includes: a lead frame having an outer surface, a lower surface, and an upper surface; a semiconductor chip on the upper surface of the lead frame and electrically connected to the lead frame; a molding layer surrounding the lead frame and the semiconductor chip, the molding layer having an outer surface coplanar with the outer surface of the lead frame; and a solder layer on the lower surface of the lead frame, wherein a width of the lead frame is greater than a width of the semiconductor chip.

### CROSS-REFERENCE TO RELATED APPLICATION

This application is based on and claims priority under 35 U.S.C. § 119 to Korean Patent Application No. 10-2023-0169855, filed on Nov. 29, 2023, in the Korean Intellectual Property Office, the disclosure of which is incorporated by reference herein in its entirety.

### BACKGROUND

### 1. Field

The disclosure relates to a semiconductor package, and more particularly, to a semiconductor device and a semiconductor package including a lead frame.

### 2. Description of Related Art

Semiconductor packaging technology has been used to package semiconductors due to demands for high integration and miniaturization of semiconductor chips. A quad flat non-leaded (QFN) package is a type of semiconductor package, is a representative of a chip scale package (CSP), and is manufactured by injection molding a metal plate on which chip pads and lead terminals are formed. The QFN package is attached to a main substrate through a solder paste or the like. At this time, there is a difference in a coefficient of thermal expansion between the QFN package and the main board.

### SUMMARY

Provided are a semiconductor device and a semiconductor package, which prevent defects in electric bonding between a lead frame and a package substrate.

Aspects of the disclosure are not limited to the aspects described above and other aspects will be clearly understood by those skilled in the art from the following specifications.

According to an aspect of the disclosure, a semiconductor device includes: a lead frame having an outer surface, a lower surface, and an upper surface; a semiconductor chip on the upper surface of the lead frame and electrically connected to the lead frame; a molding layer surrounding the lead frame and the semiconductor chip, the molding layer having an outer surface coplanar with the outer surface of the lead frame; and a solder layer on the lower surface of the lead frame, wherein a width of the lead frame is greater than a width of the semiconductor chip.

The lead frame may include a plurality of lead terminals apart from each other in a horizontal direction, wherein a lower surface of each of the plurality of lead terminals has a polygonal shape, and wherein a shape of an upper surface of the solder layer may be identical to a shape of the lower surface of the lead frame.

The solder layer may include a groove extending from an upper surface of the solder layer to a lower surface of the solder layer, and wherein a portion of a lower surface of the molding layer may be exposed to an outside through the groove.

The area of an upper surface of the solder layer may be attached to an area of the lower surface of the lead frame.

The upper surface of the lead frame may be covered by the semiconductor chip and the molding layer, and wherein the upper surface of the lead frame and the lower surface of the lead frame may be flat.

The solder layer may have a substantially constant thickness or a constant thickness in a vertical direction.

The solder layer may have a thickness of about 30 μm to about 200 μm.

The semiconductor device may further include a lower metal layer between the solder layer and the lead frame.

The lead frame may include a chip pad and a plurality of lead terminals to surround the chip pad, wherein an inactive surface of the semiconductor chip may face the lead frame, and wherein the semiconductor chip may be on the chip pad and may be electrically connected to the plurality of lead terminals by a wire.

The solder layer may cover lower surfaces of the plurality of lead terminals and may not cover a lower surface of the chip pad.

The plurality of lead terminals may not overlap the semiconductor chip in a vertical direction.

The lead frame may include a plurality of lead terminals extending out of the semiconductor chip, and wherein an active surface of the semiconductor chip may face the lead frame.

A first portion of the solder layer may overlap the semiconductor chip in a vertical direction, and wherein a second portion of the solder layer may not overlap the semiconductor chip in the vertical direction.

According to an aspect of the disclosure, a semiconductor package includes: a package substrate; a lead frame on the package substrate, the lead frame having an outer surface, a lower surface, and an upper surface; a solder bonding layer between the lead frame and the package substrate, the solder bonding layer electrically connecting the lead frame to the package substrate; a semiconductor chip on an upper surface of the lead frame, the semiconductor chip being electrically connected to the lead frame; and a molding layer surrounding the lead frame and the semiconductor chip, the molding layer having an outer surface coplanar with the outer surface of the lead frame, wherein a coefficient of thermal expansion (CTE) of the package substrate is different from a CTE of the lead frame, and wherein the solder bonding layer has a thickness of about 80 μm to about 250 μm.

The lead frame may include a plurality of lead terminals extending out of the semiconductor chip, and wherein a lower surface of each of the plurality of lead terminals may have a polygonal shape.

The solder bonding layer may cover the plurality of lead terminals, and wherein an upper surface of the solder bonding layer may correspond to a shape of the lower surface of the lead frame.

The solder bonding layer may include a groove extending from an upper surface of the solder bonding layer to a lower surface of the solder bonding layer, and wherein a lower surface of the molding layer may be exposed to an outside through the groove.

The solder bonding layer may be an outwardly convex curved surface.

According to an aspect of the disclosure, a semiconductor package includes: a package substrate; a lead frame on the package substrate, the lead frame comprising a plurality of lead terminals; a solder bonding layer between the lead frame and the package substrate, the solder bonding layer electrically connecting the lead frame to the package substrate; a semiconductor chip on an upper surface of the lead frame, the semiconductor chip being electrically connected to the lead frame; and a molding layer surrounding the lead frame and the semiconductor chip, the molding layer having an outer surface coplanar with an outer surface of the lead frame, wherein a coefficient of thermal expansion (CTE) of the package substrate is different from a CTE of the lead frame, wherein at least a portion of the lead frame is outside the semiconductor chip, wherein a lower surface of each of the plurality of lead terminals of the lead frame has a polygonal shape, and wherein a shape of an upper surface of the solder bonding layer is identical to a shape of a lower surface of the lead frame.

The solder bonding layer may have a thickness of about 80 μm to about 250 μm in a vertical direction.

### BRIEF DESCRIPTION OF THE DRAWINGS

Embodiments will be more clearly understood from the following detailed description taken in conjunction with the accompanying drawings in which:

FIG. 1 is a schematic perspective view showing a semiconductor device according to an embodiment;

FIG. 2 is a perspective view of the semiconductor device of FIG. 1 at another angle;

FIG. 3 is a schematic cross-sectional view of the semiconductor device of FIG. 1 taken along a line A-A′ of FIG. 1;

FIG. 4 is a schematic cross-sectional view of a semiconductor device taken along a line A-A′ of FIG. 1, according to an embodiment;

FIG. 5 is a schematic perspective view showing a semiconductor device according to an embodiment;

FIG. 6 is a schematic cross-sectional view of a semiconductor device of FIG. 5 taken along a line B-B′ of FIG. 5;

FIG. 7 is a schematic cross-sectional view of a semiconductor device taken along a line B-B′ of FIG. 5, according to an embodiment;

FIG. 8 is a schematic perspective view of a semiconductor package according to an embodiment; and

FIG. 9 is a schematic cross-sectional view of the semiconductor package of FIG. 8 taken along a line C-C′ of FIG. 8.

### DETAILED DESCRIPTION

As the disclosure allows for various changes and numerous embodiments, particular embodiments will be illustrated in the drawings and described in detail in the written description. However, this is not intended to limit the disclosure to particular modes of practice.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

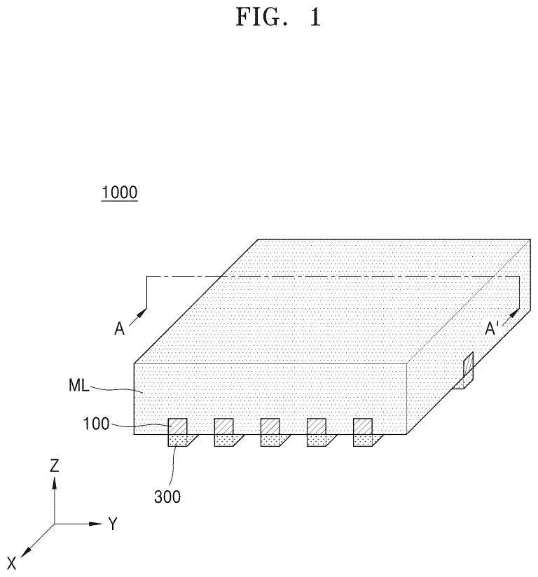

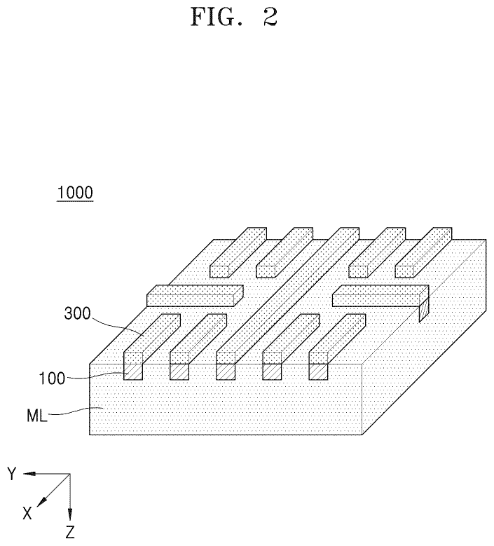

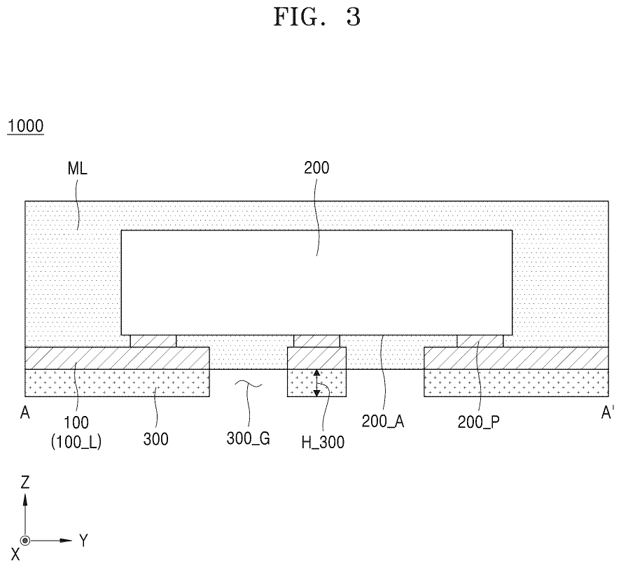

FIG. 1 is a schematic perspective view showing a semiconductor device 1000 according to an embodiment. FIG. 2 is a perspective view of the semiconductor device 1000 of FIG. 1 at another angle FIG. 3 is a schematic cross-sectional view of the semiconductor device 1000 of FIG. 1 taken along a line A-A′ of FIG. 1.

In detail, FIG. 1 is a perspective view of the semiconductor device 1000 at an angle at which an upper surface of the semiconductor device 1000 is seen, and FIG. 2 is a perspective view of the semiconductor device 1000 at an angle at which a lower surface of the semiconductor device 1000 is seen.

The semiconductor device 1000 may include a lead frame 100, a semiconductor chip 200, a molding layer ML, and a solder layer 300. For example, the semiconductor device 1000 may be referred to as a lead frame-based semiconductor package. The semiconductor device 1000 may be a quad flat no-lead (QFN) type semiconductor package.

Hereinafter, unless specifically defined, a direction parallel to an upper surface of the semiconductor chip 200 is defined as a first horizontal direction (X direction), a direction perpendicular to the upper surface of the semiconductor chip 200 is defined as a vertical direction (Z direction), and a direction perpendicular to the first horizontal direction (X direction) and the vertical direction (Z direction) is defined as a second horizontal direction (Y direction).

The semiconductor chip 200 may include an active surface 200_A and an inactive surface facing the active surface 200_A. The semiconductor chip 200 may be located on an upper surface of the lead frame 100. The semiconductor chip 200 may be electrically connected to the lead frame 100.

In some embodiments, the semiconductor chip 200 may be located on the lead frame 100 with the active surface 200_A facing the lead frame 100. That is, the semiconductor chip 200 may be placed on the lead frame 100 in a face-down manner.

In some embodiments, the semiconductor chip 200 may be electrically connected to the lead frame 100 through a connection terminal. However, the semiconductor chip 200 is not limited thereto, and the semiconductor chip 200 may be electrically connected to the lead frame 100 through adhesive films such as an anisotropic conductive film (ACF) and a non-conductive film (NCF).

For example, the semiconductor device 1000 may be a semiconductor package using a flip chip quad flat no-lead (FCQFN), in which the semiconductor chip 200 is mounted on the lead frame 100 by using a flip-chip (FC) method.

The semiconductor chip 200 may include, for example, silicon (Si). Alternatively, the semiconductor substrate may include a semiconductor element such as germanium (Ge), or a compound semiconductor such as silicon carbide (SiC), gallium arsenide (GaAs), indium arsenide (InAs), and indium phosphide (InP).

The semiconductor chip 200 may include a conductive area, for example, a well doped with impurities or a structure doped with impurities. A semiconductor device layer including separate devices may be provided on the active surface 200_A of the semiconductor chip 200. The separate devices may include, for example, a transistor. The separate devices may include microelectronic devices, for example, an image sensor such as a metal-oxide-semiconductor field effect transistor (MOSFET), a system large scale integration (system LSI), or a CMOS imaging sensor (CIS), a micro-electro-mechanical system (MEMS), an active device, and a passive device.

The semiconductor chip 200 may be a memory chip or a logic chip. The memory chip may be a volatile memory semiconductor chip such as dynamic random access memory (DRAM) and static random access memory (SRAM), or a non-volatile memory semiconductor chip such as phase-change random access memory (PRAM), magnetoresistive random access memory (MRAM), ferroelectric random access memory (FeRAM) and resistive random access memory (RRAM). The logic chip may be a central processing unit (CPU) chip, a graphics processing unit (GPU) chip, an application processor (AP) chip, or an application specific integrated circuit (ASIC) chip.

In FIG. 3, one semiconductor chip 200 is shown to be mounted on the lead frame 100, but the number of semiconductor chips 200 is not limited thereto, and two or more semiconductor chips 200 may be mounted on the lead frame 100. When two or more semiconductor chips 200 are mounted on the lead frame 100, the semiconductor chip 200 may be different types of chips.

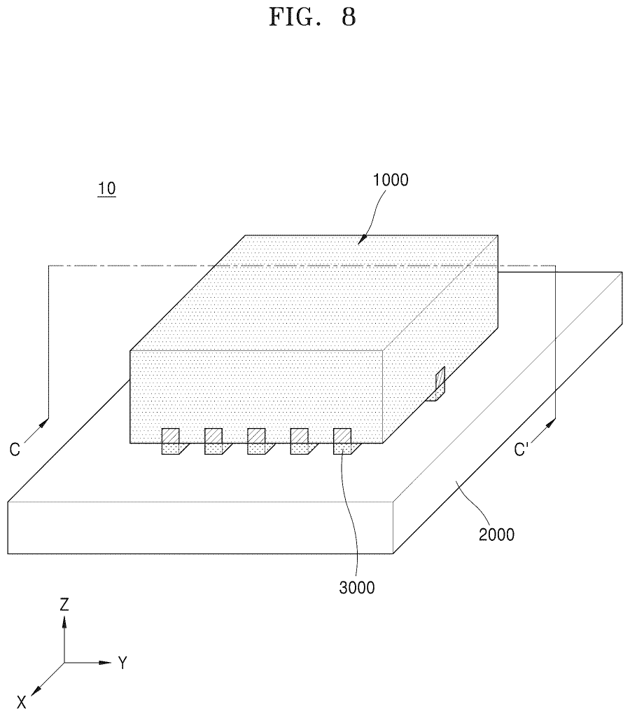

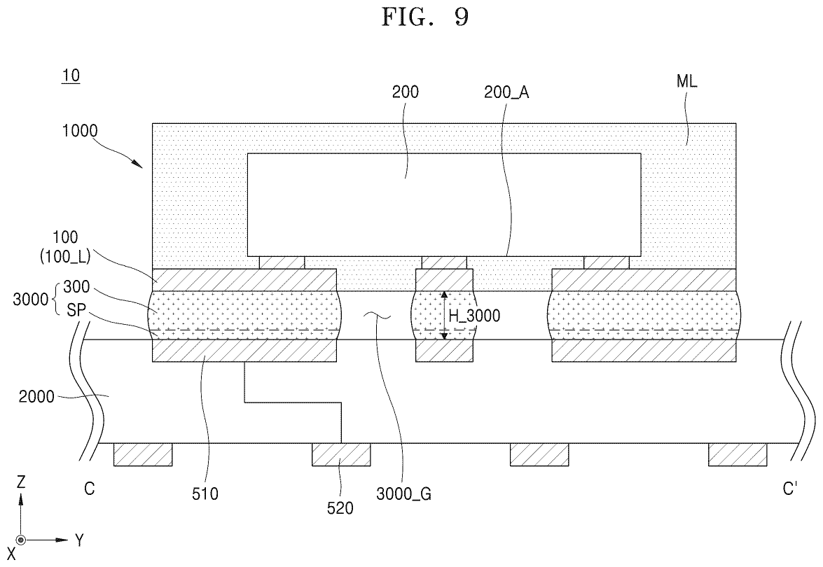

The lead frame 100 may electrically connect an input/output pad 200_P of the semiconductor chip 200 to an upper pad 510 (refer to FIG. 9) of a package substrate 2000 (refer to FIG. 8). For example, the lead frame 100 is larger than the input/output pad 200_P of the semiconductor chip 200, and may facilitate mounting of the semiconductor chip 200 on the package substrate 2000 (refer to FIG. 8).

In some embodiments, the lead frame 100 may not include a through via. For example, the lead frame 100 may include one metal layer and may not include a separate through via. For example, a distribution pattern on the upper surface of the lead frame 100 may be the same as a distribution pattern on a lower surface of the lead frame 100.

The lead frame 100 may include a plurality of lead terminals 100_L. The plurality of lead terminals 100_L may be located on a lower surface of the semiconductor chip 200. The lead frame 100 may be in contact with the input/output pad 200_P of the semiconductor chip 200 and may serve to extend the input/output pad 200_P to the outside of the semiconductor chip 200. In a planar aspect, the lead frame 100 may have a larger horizontal width than the semiconductor chip 200 and may extend to the outside of the semiconductor chip 200. That is, a side surface of the semiconductor chip 200 may be located on the upper surface of the lead frame 100. In the specification, the “planar aspect” means an aspect viewed from above to below in the vertical direction (Z direction).

Each of the plurality of lead terminals 100_L may be in contact with the input/output pad 200_P of the semiconductor chip 200. A portion of the plurality of lead terminals 100_L may overlap the semiconductor chip 200 in the vertical direction (Z direction), and the other portion of the lead terminals 100_L may not overlap the semiconductor chip 200 in the vertical direction (Z direction). A portion of each of the plurality of lead terminals 100_L, which is in contact with the input/output pad 200_P of the semiconductor chip 200, may overlap the semiconductor chip 200 in the vertical direction (Z direction), and a portion of each of the plurality of lead terminals 100_L, which extends the input/output pad 200_P of the semiconductor chip 200, may not overlap the semiconductor chip 200 in the vertical direction (Z direction).

In some embodiments, the plurality of lead terminals 100_L may be apart from each other in a horizontal direction. For example, the plurality of lead terminals 100_L may be electrically connected to different input/output pads 200_P from among the input/output pads 200_P of the semiconductor chip 200.

In some embodiments, a lower surface of each of the plurality of lead terminals 100_L may have a polygonal shape. For example, the lower surface of each of the plurality of lead terminals 100_L may have a polygonal shape, such as a square shape or a pentagonal shape.

In some embodiments, a lower surface of each of the plurality of lead terminals 100_L may have a square shape with a high aspect ratio. When each of the plurality of lead terminals 100_L extends from a lower portion of the semiconductor chip 200 to the outside, each of the plurality of lead terminals 100_L may be narrow and may extend long.

The molding layer ML may surround the lead frame 100 and the semiconductor chip 200. For example, the molding layer ML may be located between the plurality of lead terminals 100_L of the lead frame 100 and may be formed to cover the semiconductor chip 200. A lower surface of the molding layer ML may be coplanar with the lower surface of the lead frame 100.

As shown in FIG. 2, an outer surface (e.g., a surface extending in the Y and Z directions) of the molding layer ML may be coplanar with an outer surface (e.g., a surface extending in the Y and Z directions) of the lead frame 100. For example, the outer surface of the lead frame 100 and the outer surface of the molding layer ML, may become an outer surface of the semiconductor device 1000, and a portion of the lead frame 100 may be exposed out of the semiconductor device 1000.

In some embodiments, the upper surface of the lead frame 100 may be covered by the molding layer ML and the semiconductor chip 200. That is, the plurality of lead terminals 100_L of the lead frame 100 may not protrude out of the molding layer ML.

In some embodiments, the lead frame 100 may have a flat plate shape. For example, the lead frame 100 may have a flat plate shape with no portion in which a vertical level changes in the vertical direction (Z direction). For example, the lower surface and the upper surface of the lead frame 100 may each be flat.

In some embodiments, the molding layer ML may include epoxy resin or polyimide resin. The molding layer ML may include, for example, epoxy molding compound (EMC).

The solder layer 300 may be located on the lower surface of the lead frame 100. For example, the solder layer 300 may cover the lower surface of the lead frame 100. For example, the solder layer 300 may be conformally formed on the lower surface of the lead frame 100. That is, the solder layer 300 may have a flat plate shape.

In some embodiments, a height H_300 of the solder layer 300 in the vertical direction (Z direction) may be constant. The height H_300 of the solder layer 300 in the vertical direction (Z direction) may be about 30 μm to about 200 μm.

The solder layer 300 may be in contact with the plurality of lead terminals 100_L of the lead frame 100. For example, a lower surface of the solder layer 300 may have the same shape as the lower surface of the lead frame 100. In other words, the solder layer 300 may correspond to a shape of the lead frame 100. In some embodiments, an area of an upper surface of the solder layer 300 may be equal to an area of the lower surface of the lead frame 100.

In some embodiments, a portion of the solder layer 300 may overlap the semiconductor chip 200 in the vertical direction (Z direction), and the other portion of the solder layer 300 may not overlap the semiconductor chip 200 in the vertical direction (Z direction).

In some embodiments, the solder layer 300 may include a groove 300_G extending from the upper surface to the lower surface of the solder layer 300. For example, the solder layer 300 may cover the lower surface of the lead frame 100 but may not cover a lower surface of the molding layer ML. For example, the groove 300_G of the solder layer 300 may be located below the molding layer ML. The groove 300_G of the solder layer 300 may be located in a separation space between the plurality of lead terminals 100_L. A portion of the lower surface of the molding layer ML may be exposed to the outside by the groove 300_G of the solder layer 300.

For example, the solder layer 300 may include at least one alloy selected from the group consisting of Sn—Ag—Cu alloy, Sn—Bi alloy, Sn—Bi—Ag alloy, or Sn—Ag—Cu—Ni alloy. For example, the solder layer 300 may include at least one of Sn—Ag (0.3 to 3)-Cu (0.1 to 1), Sn—Bi (35 to 75), Sn—Bi (35 to 75)-Ag (0.1 to 20), and Sn—Ag (0.5 to 5)-Cu (0.1 to 2)-Ni (0.05 to 0.1). For example, when the solder layer 300 includes Sn—Ag—Cu alloy, the solder layer 300 may include SAC305 (Sn-3.0 Ag-0.5 Cu) or SAC205 (Sn-2.0 Ag-0.5 Cu).

The semiconductor device 1000 may include the solder layer 300, and when the semiconductor device 1000 is mounted on an external substrate, a separation distance between the semiconductor device 1000 and the external substrate may be relatively large. In other words, when the solder layer 300 (refer to FIG. 9) is positioned between the semiconductor device 1000 and the external substrate, the thickness of a solder bonding layer 3000 (refer to FIG. 9) that electrically connects the semiconductor device 1000 to the external substrate may increase.

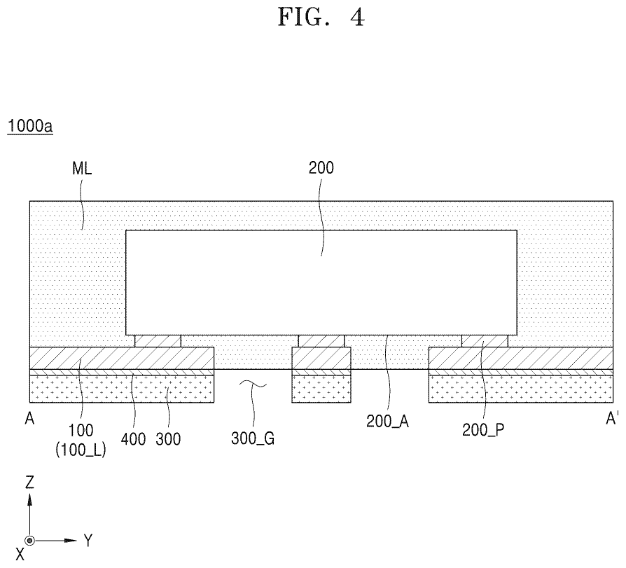

FIG. 4 is a schematic cross-sectional view of a semiconductor device 1000a taken along a line A-A′ of FIG. 1, according to an embodiment.

Most of the components constituting the semiconductor device 1000a described below and the materials constituting the components are substantially the same or similar to the above description of FIG. 1. Therefore, for the convenience of the description, the semiconductor device 1000a of FIG. 4 is described in terms of a difference from the semiconductor device 1000 of FIG. 1.

Referring to FIG. 4, the semiconductor device 1000a may further include a lower metal layer 400. The lower metal layer 400 may be located between the lead frame 100 and the solder layer 300. A shape of a lower surface of the lower metal layer 400 may be the same as a shape of the lower surface of the lead frame 100. The lower metal layer 400 may prevent the solder layer 300 from direct contact with the lead frame 100.

The lower metal layer 400 may be a seed layer, an adhesive layer, or a barrier layer for forming the solder layer 300. According to embodiments, the lower metal layer 400 may include chromium (Cr), tungsten (W), titanium (Ti), copper (Cu), nickel (Ni), aluminum (Al), palladium (Pd), gold (Au) or a combination thereof.

In FIG. 4, the lower metal layer 400 is shown as one layer, but unlike this, the lower metal layer 400 may have a stacked structure including a plurality of metal layers. For example, the lower metal layer 400 may include a first metal layer, a second metal layer, and/or a third metal layer sequentially stacked on a lead frame 100.

The first metal layer may function as an adhesive layer to stably attach the solder layer 300 formed thereon to the lead frame 100. For example, the first metal layer may include at least one of titanium (Ti), titanium-tungsten (Ti—W), chromium (Cr), and aluminum (Al).

The second metal layer may function as a barrier layer that prevents a solder material included in the solder layer 300 from spreading. The second metal layer may include at least one of copper (Cu), nickel (Ni), chromium-copper (Cr—Cu) and nickel vanadium (Ni—V).

The third metal layer may function as a wetting layer to improve the wetting characteristics of the seed layer for forming the solder layer 300. The third metal layer may include at least one of nickel (Ni), copper (Cu), and aluminum (Al).

In the semiconductor device 1000a, the lead frame 100 and the solder layer 300 are not only stably bonded to each other through the lower metal layer 400 but also may prevent performance degradation of the lead frame 100. The semiconductor device 1000a may include the solder layer 300 located on the lower surface of the lead frame 100, and when the semiconductor device 1000a is later attached to the package substrate 2000 (refer to FIG. 8), the solder bonding layer 3000 (refer to FIG. 8) may be thick. Accordingly, occurrence of defects in bonding of the semiconductor device 1000a and the package substrate 2000 may be prevented.

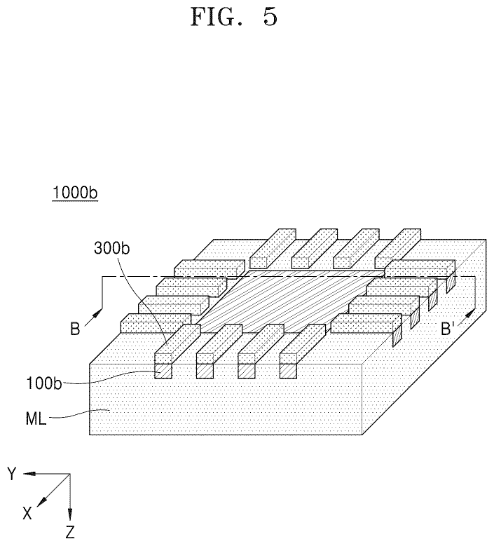

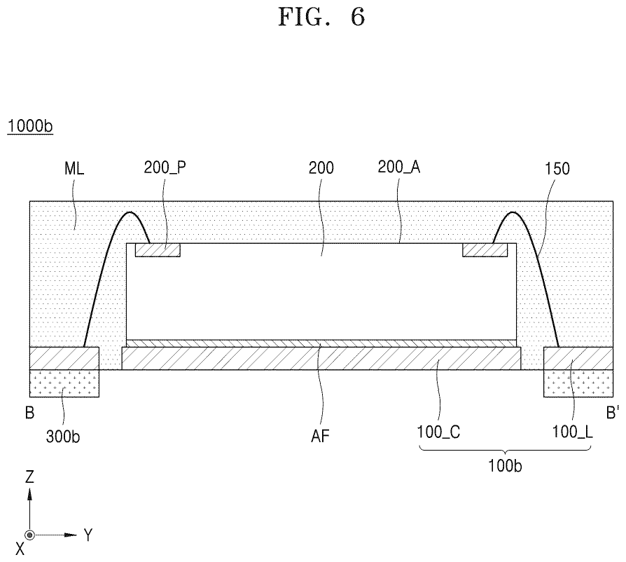

FIG. 5 is a schematic perspective view showing a semiconductor device 1000b according to an embodiment. FIG. 6 is a schematic cross-sectional view of the semiconductor device 1000b of FIG. 5 taken along a line B-B′ of FIG. 5.

Most of the components constituting the semiconductor device 1000b described below and the materials constituting the components are substantially the same or similar to the above description of FIG. 1. Therefore, for the convenience of the description, the semiconductor device 1000b of FIG. 5 is described in terms of a difference from the semiconductor device 1000 of FIG. 1.

Referring to FIGS. 5 and 6, the semiconductor device 1000b may include the lead frame 100b, the semiconductor chip 200, the molding layer ML, and the solder layer 300. The semiconductor device 1000b may be a QFN type semiconductor package.

The lead frame 100b may be located below the semiconductor chip 200. The lead frame 100b may include a chip pad 100_C and the plurality of lead terminals 100_L. The plurality of lead terminals 100_L and the chip pad 100_C may be apart from each other in a horizontal direction. The plurality of lead terminals 100_L may be located to surround the chip pad 100_C. For example, the chip pad 100_C may be located in a center area of the lead frame 100b, and the plurality of lead terminals 100_L may surround the chip pad 100_C and be located in an edge area of the lead frame 100b.

In some embodiments, the molding layer ML may be located between the chip pad 100_C and the plurality of lead terminals 100_L. For example, a gap between the chip pad 100_C and the plurality of lead terminals 100_L may be fixed by the molding layer ML.

In some embodiments, an area of an upper surface of the chip pad 100_C may be larger than an area of each of the plurality of lead terminals 100_L. An aspect ratio of the chip pad 100_C may be lower than an aspect ratio of each of the plurality of lead terminals 100_L. That is, each of the plurality of lead terminals 100_L may be narrower and longer than the chip pad 100_C. In some embodiments, an area of each of the plurality of lead terminals 100_L may be less than an area of the chip pad 100_C.

In some embodiments, the chip pad 100_C may overlap the semiconductor chip 200 in the vertical direction (Z direction), and the plurality of lead terminals 100_L may not overlap the semiconductor chip 200 in the vertical direction (Z direction). For example, from a planar aspect, the plurality of lead terminals 100_L may be apart from the semiconductor chip 200 in a horizontal direction.

In some embodiments, the chip pad 100_C may be a heat dissipation pad that helps dissipate heat generated in the semiconductor chip 200. The plurality of lead terminals 100_L may be electrically connected to the input/output pad 200_P of the semiconductor chip 200 and may electrically connect the semiconductor chip 200 to the package substrate 2000 (refer to FIG. 8). For example, the chip pad 100_C may include a conductive material or a non-conductive material, and the plurality of lead terminals 100_L may include a conductive material.

The semiconductor chip 200 may include the active surface 200_A and an inactive surface facing the active surface 200_A. The semiconductor chip 200 may be located on the upper surface of the lead frame 100b and may be electrically connected to the lead frame 100b. For example, the semiconductor chip 200 may be located on the chip pad 100_C of the lead frame 100b and may be electrically connected to the plurality of lead terminals 100_L.

In some embodiments, the semiconductor chip 200 may be located on the lead frame 100b with the inactive surface facing the lead frame 100b. For example, the input/output pad 200_P of the semiconductor chip 200 may face an upper portion of the semiconductor chip 200. That is, the semiconductor chip 200 may be placed on the lead frame 100b in a face-up manner.

In some embodiments, the semiconductor chip 200 may be attached onto the chip pad 100_C. The semiconductor chip 200 may be attached onto the chip pad 100_C through an adhesive film AF. However, a method of attaching the semiconductor chip 200 to the chip pad 100_C is not limited thereto, and various methods commonly used in the art may be used.

In some embodiments, the semiconductor chip 200 may be electrically connected to the lead frame 100b through a wire 150. For example, the wire 150 may electrically connect the input/output pad 200_P of the semiconductor chip 200 to the upper pad 510 (refer to FIG. 9) of the package substrate 2000 (refer to FIG. 8). For example, the semiconductor device 1000 may be a QFN type semiconductor package in which the semiconductor chip 200 is mounted on the lead frame 100b using a wire bonding method.

A solder layer 300b may be located on a lower surface of the lead frame 100b. For example, the solder layer 300b may cover the lower surface of the plurality of lead terminals 100_L of the lead frame 100b but may not cover the lower surface of the chip pad 100_C of the lead frame 100b. That is, the solder layer 300b may overlap the plurality of lead terminals 100_L in the vertical direction (Z direction) but may not overlap the chip pad 100_C in the vertical direction (Z direction). The lower surface of the chip pad 100_C may be exposed to the outside.

In some embodiments, the solder layer 300b may not overlap the semiconductor chip 200 in a vertical direction. For example, the solder layer 300b may be located below an edge area of the lead frame 100b, and the semiconductor chip 200 may be located above a center area of the lead frame 100b, and thus the solder layer 300b and the semiconductor chip 200 may not overlap each other.

In some embodiments, a height of the solder layer 300b in the vertical direction (Z direction) may be constant. The height of the solder layer 300 in the vertical direction (Z direction) may be about 30 μm to about 200 μm.

The semiconductor device 1000b may include the solder layer 300b located on the lower surface of the lead frame 100b, and when the semiconductor device 1000b is mounted on an external substrate, a separation distance between the semiconductor device 1000b and the external substrate may be relatively large. In other words, when the solder layer 300b is positioned between the semiconductor device 1000b and the external substrate, the thickness of the solder bonding layer 3000 (refer to FIG. 9) that electrically connects the semiconductor device 1000b to the external substrate may increase.

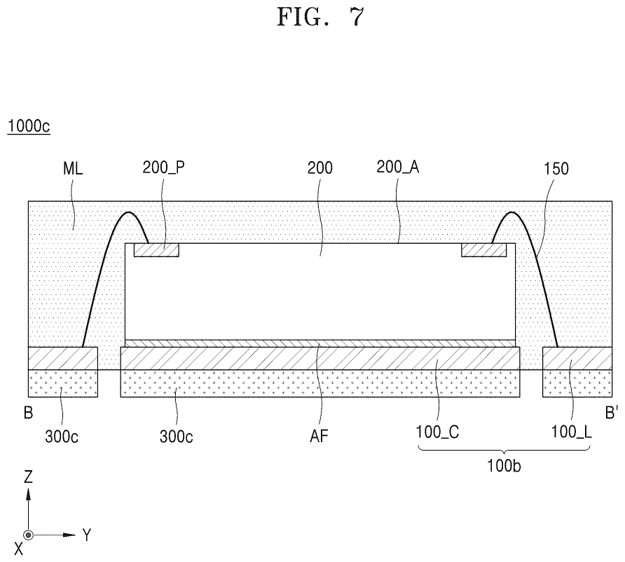

FIG. 7 is a schematic cross-sectional view of a semiconductor device 1000c taken along a line B-B′ of FIG. 5, according to an embodiment.

Most of the components constituting the semiconductor device 1000c described below and the materials constituting the components are substantially the same or similar to the above description of FIG. 5. Therefore, for the convenience of the description, the semiconductor device 1000c of FIG. 7 is described in terms of a difference from the semiconductor device 1000b of FIG. 5.

The semiconductor device 1000c may include a solder layer 300c. The solder layer 300c may be located on a lower surface of the lead frame 100b. The solder layer 300c may be located on the chip pad 100_C and the plurality of lead terminals 100_L of the lead frame 100b. For example, the solder layer 300c may cover the lower surface of the lead frame 100b.

In some embodiments, a shape of a lower surface of the solder layer 300c may be equal to an area of a lower surface of the lead frame 100b. For example, the lower surface of the solder layer 300c may be shaped as a plurality of squares in a horizontal direction. An area of the lower surface of the solder layer 300c may be equal to an area of the lower surface of the lead frame 100b. At this time, an area of a lower surface of the lead frame 100b may be the sum of an area of the lower surface of the chip pad 100_C and an area of the lower surface of the plurality of lead terminals 100_L.

In some embodiments, the solder layer 300c may completely cover the lower surface of the lead frame 100b and may not cover the lower surface of the molding layer ML. For example, a portion of the lower surface of the molding layer ML may be exposed to the outside.

In some embodiments, the solder layer 300c may have a flat plate shape with a constant thickness in the vertical direction (Z direction). For example, the solder layer 300c may have a thickness of about 30 μm to about 200 μm.

An area of the solder layer 300c of the semiconductor device 1000c may be relatively large, and thus when the semiconductor device 1000c is later mounted on an external substrate, a bonding force between the semiconductor device 1000c and the external substrate may increase. The thickness of the solder bonding layer 3000 (refer to FIG. 9) between the semiconductor device 1000c and the external substrate may increase, thereby increasing the lifespan of the solder bonding layer 3000.

FIG. 8 is a schematic perspective view showing a semiconductor package 10 according to an embodiment. FIG. 9 is a schematic cross-sectional view of the semiconductor package 10 of FIG. 8 taken along a line C-C′ of FIG. 8.

Referring to FIGS. 8 and 9, the semiconductor package 10 may include a package substrate 2000, a semiconductor device 1000, and a solder bonding layer 3000.

The package substrate 2000 may include, for example, a printed circuit board (PCB). The package substrate 2000 may include a core insulating layer including at least one material selected from phenol resin, epoxy resin, and polyimide. For example, the core insulating layer may include at least one material selected from polyimide, flame retardant 4 (FR-4), tetrafunctional epoxy, polyphenylene ether, and epoxy/polyphenylene oxide, bismaleimide triazine (BT), thermount, cyanate ester, and liquid crystal polymer.

However, the disclosure is not limited thereto, and in some embodiments, the package substrate 2000 may be an interposer including a substrate and a through via formed to pass through the substrate. For example, the package substrate 2000 may be a glass interposer or a silicon interposer. In some embodiments, the package substrate 2000 may be a redistribution structure that includes a redistribution pattern and a redistribution insulating layer surrounding the redistribution pattern.

In some embodiments, the package substrate 2000 may include an upper pad 510 located on the upper surface of the core insulating layer and a lower pad 520 located on the lower surface of the core insulating layer. The upper pad 510 and the lower pad 520 may be a portion of a circuit wiring patterned after covering an upper surface and a lower surface of the core insulating layer with copper foil (Cu foil). In detail, the upper pad 510 and the lower pad 520 may be areas of the circuit wiring, which are not covered by a solder resist layer and are exposed to the outside.

In some embodiments, the upper pad 510 and the lower pad 520 may each include copper, nickel, stainless steel or beryllium copper. An internal wiring may be formed within the package substrate 2000 to electrically connect the upper pad 510 to the lower pad 520.

In some embodiments, external connection terminals may be attached to the lower pad 520. The external connection terminals may be configured to electrically and physically connect the package substrate 2000 to an external device on which the package substrate 2000 is mounted. The external connection terminals may be formed, for example, from a solder ball or a solder bump.

The semiconductor device 1000 may include the lead frame 100, the semiconductor chip 200, and the molding layer ML. The semiconductor device 1000 may be the semiconductor devices 1000a (in FIG. 3), 1000b (in FIG. 4), 1000c (in FIG. 6), and 1000d (in FIG. 7) described above. Repeated descriptions of the above-described semiconductor device from among the components and materials constituting the components of the semiconductor device 1000 are omitted, and a difference therebetween is described.

The lead frame 100 may be located on the upper surface of the package substrate 2000, the semiconductor chip 200 may be located on the upper surface of the lead frame 100, and the molding layer ML may cover the lead frame 100 and the semiconductor chip 200. The lead frame 100 may be electrically connected to the semiconductor chip 200, and the input/output pad of the semiconductor chip 200 may extend to the outside. The molding layer ML may protect the lead frame 100 and the semiconductor chip 200 from the outside.

In some embodiments, a coefficient of thermal expansion (CTE) of the lead frame 100 may be different from a CTE of the package substrate 2000. When the temperature of the semiconductor package 10 increases, an extension degree of the lead frame 100 may be different from an extension degree of the package substrate 2000. For example, the CTE of the lead frame 100 may be less than that of the package substrate 2000. At this time, when the temperature of the semiconductor package 10 increases, a change in volume of the lead frame 100 may be less than a change in volume of the package substrate 2000.

The solder bonding layer 3000 may be located between the lead frame 100 and the package substrate 2000. The lead frame 100 and the molding layer ML may be apart from the package substrate 2000 in the vertical direction (Z direction). For example, lower surfaces of the lead frame 100 and the molding layer ML may be apart from the upper surface of the package substrate 2000 by a thickness H_3000 of the solder bonding layer 3000.

The solder bonding layer 3000 may include a solder paste SP located on the solder layer 300 of the semiconductor device 1000 described above and the upper pad 510 of the package substrate 2000. For example, the solder bonding layer 3000 may be formed by bonding the solder layer 300 to the solder paste SP by heat.

For example, the solder bonding layer 3000 may include at least one alloy selected from the group consisting of Sn—Ag—Cu alloy, Sn—Bi alloy, Sn—Bi—Ag alloy, or Sn—Ag—Cu—Ni alloy. For example, the solder bonding layer 3000 may include at least one of Sn—Ag (0.3 to 3)-Cu (0.1 to 1), Sn—Bi (35 to 75), Sn—Bi (35 to 75)-Ag (0.1 to 20), and Sn—Ag (0.5 to 5)-Cu (0.1 to 2)-Ni (0.05 to 0.1). For example, when the solder bonding layer 3000 includes Sn—Ag—Cu alloy, the solder bonding layer 3000 may include SAC305 (Sn-3.0 Ag-0.5 Cu) or SAC205 (Sn-2.0 Ag-0.5 Cu).

The solder bonding layer 3000 may electrically connect the plurality of lead terminals 100_L of the lead frame 100 to the upper pad 510 of the package substrate 2000 and may adhere the semiconductor device 1000 onto the package substrate 2000.

In some embodiments, the solder bonding layer 3000 may cover the lower surface of the lead frame 100 and may not cover the lower surface of the molding layer ML. For example, the shape of the upper surface of the solder bonding layer 3000 may be substantially the same as the shape of the lower surface of the lead frame 100.

In some embodiments, the solder bonding layer 3000 may include the groove 3000_G extending from the upper surface to the lower surface of the solder bonding layer 3000. A portion of the lower surface of the molding layer ML may be exposed out of the semiconductor device 1000 by the groove 3000_G of the solder bonding layer 3000. For example, an air gap or an underfill material may be located between the molding layer ML and the package substrate 2000. That is, the inside of the groove 3000_G of the solder bonding layer 3000 may be filled with air or an underfill material.

In some embodiments, the thickness H_3000 of the solder bonding layer 3000 may be about 80 μm to about 250 μm. For example, the thickness H_3000 of the solder bonding layer 3000 may be equal to the sum of the thicknesses of the solder layer 300 and the solder paste SP.

In some embodiments, a side surface of the solder bonding layer 3000 may be curved. For example, the side surface of the solder bonding layer 3000 may be an outwardly convex curved surface. A curvature of the side surfaces of the solder bonding layer 3000 may be relatively small. The solder bonding layer 3000 may have a shape in which the solder layer 300 and the solder paste SP are bonded and have the thickness H_3000 that is relatively large, and thus may have a relatively small curvature.

The CTE of the lead frame 100 and the CTE of the package substrate 2000 may be different. Accordingly, the lead frame 100 and the package substrate 2000 may be damaged by the solder bonding layer 3000 that electrically and mechanically connects the lead frame 100 to the package substrate 2000.

In detail, the upper surface of the solder bonding layer 3000 may be in contact with the lead frame 100 and may be affected by a change in the volume of the lead frame 100. The lower surface of the solder bonding layer 3000 may be in contact with the package substrate 2000 and may be affected by a change in the volume of the package substrate 2000. That is, the change in the volume of the lead frame 100 and the change in the volume of the package substrate 2000 may apply external force to the upper surface and the lower surface of the solder bonding layer 3000, respectively. A difference in the external force applied to the upper surface and the lower surface of the solder bonding layer 3000 may apply shear stress to the solder bonding layer 3000, causing damage to the solder bonding layer 3000.

For example, when the CTE of the lead frame 100 is less than that of the package substrate 2000, if the temperature of the semiconductor package 10 increases, the change in the volume of the lead frame 100 may be less than the change in the volume of the package substrate 2000. At this time, the external force applied to the upper surface of the solder bonding layer 3000 may be less than the external force applied to the lower surface of the solder bonding layer 3000, and thus shear stress may be applied to the solder bonding layer 3000. That is, the solder bonding layer 3000 may be damaged by shear stress generated due to temperature changes of the semiconductor package 10.

A relationship between the shear stress of the solder bonding layer 3000 and a height of the solder bonding layer 3000 is γ=Δδ/H. At this time, “γ” refers to shear stress, “Δδ” refers to a difference in area change between two opposite surfaces, and “H” refers to a distance between the two opposite surfaces.

In the case of the solder bonding layer 3000, 48 refers to a difference between a change in area of the upper surface of the solder bonding layer 3000 in contact with the lead frame 100 and a change in area of the lower surface of the solder bonding layer 3000 in contact with the package substrate 2000, and H refers to a distance between the upper surface and the lower surface of the solder bonding layer 3000, that is, the thickness H_3000 of the solder bonding layer 3000 in the vertical direction (Z direction).

As the thickness H_3000 of the solder bonding layer 3000 increases, the magnitude of the shear stress applied to the solder bonding layer 3000 may decrease. That is, as the thickness H_3000 of the solder bonding layer 3000 increases, the lifespan of the solder bonding layer 3000 may extend.

In the case of the existing QFN type semiconductor package, the lower surface of the lead frame 100 is exposed to the outside, and the lead frame 100 may be attached to the package substrate 2000 through a thin solder bonding layer by using the solder paste SP alone without the solder layer 300.

The semiconductor device 1000 of the disclosure may include the solder layer 300 located on the lower surface of the lead frame 100. In a process of attaching the semiconductor device 1000 to the package substrate 2000, the solder layer 300 and the solder paste SP may be bonded to each other to form the solder bonding layer 3000. Accordingly, the thickness H_3000 of the solder bonding layer 3000 formed by bonding the solder layer 300 and the solder paste SP to each other may be relatively large, and thus the lifespan of the solder bonding layer 3000 may extend.

With regard to the solder bonding layer 3000, the solder layer 300, which is relatively thick, may be previously formed, and thus voids may be prevented from being formed in the solder bonding layer 3000 during a process of attaching the semiconductor device 1000 to the package substrate 2000. The reliability of electrical and mechanical bonding between the semiconductor device 1000 and the package substrate 2000 may be improved, and thus the lifespan of the semiconductor package 10 may extend.

Thus far, the disclosure has been described with reference to the embodiments shown in the drawings, but these are merely illustrative, and those skilled in the art will understand that various modifications and other equivalent embodiments are possible therefrom. Therefore, the true scope of the disclosure needs to be determined by the technical spirit of the claims.

While the disclosure has been particularly shown and described with reference to embodiments thereof, it will be understood that various changes in form and details may be made therein without departing from the spirit and scope of the following claims.

What is claimed is:

1. A semiconductor device comprising:
a lead frame having an outer surface, a lower surface, and an upper surface;
a semiconductor chip on the upper surface of the lead frame and electrically connected to the lead frame;
a molding layer surrounding the lead frame and the semiconductor chip, the molding layer having an outer surface coplanar with the outer surface of the lead frame; and
a solder layer on the lower surface of the lead frame,
wherein a width of the lead frame is greater than a width of the semiconductor chip.

2. The semiconductor device of claim 1, wherein the lead frame comprises a plurality of lead terminals apart from each other in a horizontal direction,
wherein a lower surface of each of the plurality of lead terminals has a polygonal shape, and
wherein a shape of an upper surface of the solder layer is identical to a shape of the lower surface of the lead frame.

3. The semiconductor device of claim 1, wherein the solder layer comprises a groove extending from an upper surface of the solder layer to a lower surface of the solder layer, and
wherein a portion of a lower surface of the molding layer is exposed to an outside through the groove.

4. The semiconductor device of claim 1, wherein an area of an upper surface of the solder layer is attached to an area of the lower surface of the lead frame.

5. The semiconductor device of claim 1, wherein the upper surface of the lead frame is covered by the semiconductor chip and the molding layer, and
wherein the upper surface of the lead frame and the lower surface of the lead frame are flat.

6. The semiconductor device of claim 1, wherein the solder layer has a substantially constant thickness or a constant thickness in a vertical direction.

7. The semiconductor device of claim 6, wherein the solder layer has a thickness of about 30 μm to about 200 μm.

8. The semiconductor device of claim 1, further comprising a lower metal layer between the solder layer and the lead frame.

9. The semiconductor device of claim 1, wherein the lead frame comprises a chip pad and a plurality of lead terminals to surround the chip pad,
wherein an inactive surface of the semiconductor chip faces the lead frame, and
wherein the semiconductor chip is on the chip pad and is electrically connected to the plurality of lead terminals by a wire.

10. The semiconductor device of claim 9, wherein the solder layer covers lower surfaces of the plurality of lead terminals and does not cover a lower surface of the chip pad.

11. The semiconductor device of claim 9, wherein the plurality of lead terminals do not overlap the semiconductor chip in a vertical direction.

12. The semiconductor device of claim 1, wherein the lead frame comprises a plurality of lead terminals extending out of the semiconductor chip, and
wherein an active surface of the semiconductor chip faces the lead frame.

13. The semiconductor device of claim 12, wherein a first portion of the solder layer overlaps the semiconductor chip in a vertical direction, and
wherein a second portion of the solder layer does not overlap the semiconductor chip in the vertical direction.

14. A semiconductor package comprising:
a package substrate;
a lead frame on the package substrate, the lead frame having an outer surface, a lower surface, and an upper surface;
a solder bonding layer between the lead frame and the package substrate, the solder bonding layer electrically connecting the lead frame to the package substrate;
a semiconductor chip on an upper surface of the lead frame, the semiconductor chip being electrically connected to the lead frame; and
a molding layer surrounding the lead frame and the semiconductor chip, the molding layer having an outer surface coplanar with the outer surface of the lead frame,
wherein a coefficient of thermal expansion (CTE) of the package substrate is different from a CTE of the lead frame, and
wherein the solder bonding layer has a thickness of about 80 μm to about 250 μm.

15. The semiconductor package of claim 14, wherein the lead frame comprises a plurality of lead terminals extending out of the semiconductor chip, and
wherein a lower surface of each of the plurality of lead terminals has a polygonal shape.

16. The semiconductor package of claim 15, wherein the solder bonding layer covers the plurality of lead terminals, and
wherein an upper surface of the solder bonding layer corresponds to a shape of the lower surface of the lead frame.

17. The semiconductor package of claim 14, wherein the solder bonding layer comprises a groove extending from an upper surface of the solder bonding layer to a lower surface of the solder bonding layer, and
wherein a lower surface of the molding layer is exposed to an outside through the groove.

18. The semiconductor package of claim 14, wherein the solder bonding layer is an outwardly convex curved surface.

19. A semiconductor package comprising:
a package substrate;
a lead frame on the package substrate, the lead frame comprising a plurality of lead terminals;
a solder bonding layer between the lead frame and the package substrate, the solder bonding layer electrically connecting the lead frame to the package substrate;
a semiconductor chip on an upper surface of the lead frame, the semiconductor chip being electrically connected to the lead frame; and
a molding layer surrounding the lead frame and the semiconductor chip, the molding layer having an outer surface coplanar with an outer surface of the lead frame,
wherein a coefficient of thermal expansion (CTE) of the package substrate is different from a CTE of the lead frame,
wherein at least a portion of the lead frame is outside the semiconductor chip, wherein a lower surface of each of the plurality of lead terminals of the lead frame has a polygonal shape, and
wherein a shape of an upper surface of the solder bonding layer is identical to a shape of a lower surface of the lead frame.

20. The semiconductor package of claim 19, wherein the solder bonding layer has a thickness of about 80 μm to about 250 μm in a vertical direction.
